(19) United States
(12) Patent Application Publication
(10) Pub. No.: US 2011/0003467 A1
(43) Pub. Date: Jan. 6, 2011

(54) METHOD OF MANUFACTURING SEMICONDUCTOR DEVICE

(75) Inventor: Takayuki KANDA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/826,348

(22) Filed: Jun. 29, 2010

(30) Foreign Application Priority Data
Jul. 6, 2009 (JP) 2009-159678

(51) Int. Cl. H01L 21/28; H01L 21/30

(52) U.S. Cl. 438/585; 438/703; 257/E21.192; 257/E21.211

(57) ABSTRACT

A method of forming a semiconductor device includes the following processes. A nitrogen-diffusion region is selectively formed in a semiconductor substrate having first and second regions. The nitrogen-diffusion region is at a shallow level of the first region. A first heat treatment is carried out to form a first oxide layer over the semiconductor substrate. The first oxide layer includes first and second portions. The first portion is in the first region. The second portion is in the second region. The first portion is thinner than the second portion.

### BACKGROUND OF THE INVENTION

1. Field of the Invention

The present invention relates to a method of manufacturing a semiconductor device.

Priority is claimed on Japanese Patent Application No. 2009-159678, filed Jul. 6, 2009, the content of which is incorporated herein by reference.

2. Description of the Related Art

In the related art, a semiconductor device is known which include plural different transistors that are mounted on a semiconductor substrate. In some cases, such a semiconductor device may include a semiconductor memory and peripheral circuits thereof. The plural different transistors on the same semiconductor substrate need to have different thicknesses of gate oxide films (silicon oxide films). Multi-oxide processes are necessary to form silicon oxide films with different thicknesses over the same semiconductor substrate.

Japanese Unexamined Patent Application Publication No. 2000-3965 discloses a method of forming silicon oxide films having different thicknesses on the same semiconductor substrate. A nitride layer is partially formed on the semiconductor substrate by a plasma nitridation process. The formation of the nitride layer will decrease silicon oxidation rate.

Japanese Unexamined Patent Application Publications Nos. 2000-12795 and 2004-134719 disclose that nitrogen ions are implanted into an area of a substrate. The area of a substrate is an area on which a silicon oxide film is to be formed. For each area, the process of implantation of nitrogen ions will control the rate of silicon oxidation. Silicon oxide films having different thicknesses are formed by a single oxidation process.

Japanese Unexamined Patent Application Publication No. 2008-16499 discloses that a first oxidation process is carried out in a dried gas and a second oxidation process is carried out in a moisture vapor. The two processes will adjust the thicknesses of silicon oxide films.

The related art can forms silicon oxide films having different thicknesses on the same semiconductor substrate. In the process, a first silicon oxide film is formed. Then, the first silicon oxide film is removed in a thin film portion region. Further a second silicon oxide film is formed, thereby forming a thick film portion and a thin film portion. In this case, the thick film portion is the stack of the first and second silicon oxide films.

According to the above method, the thick film portion has been formed by the two oxidation processes. Before the second silicon oxide film is formed, the first silicon oxide film is cleaned and the surface of the first silicon oxide film is removed. For this reason, the first and second oxidation processes and the cleaning process make it difficult to secure the reliability on insulation of the thick film portion. The thick film portion includes the stack of the first and second silicon oxide films, wherein the second silicon oxide film is disposed on the first silicon oxide film. Removing the first silicon oxide film affects the thickness of the thick film portion, which will make it difficult to control the thickness of the thick film portion.

### SUMMARY

In one embodiment, a method of forming a semiconductor device may include, but is not limited to, the following processes. A nitrogen-diffusion region is selectively formed in a semiconductor substrate having first and second regions. The nitrogen-diffusion region is at a shallow level of the first region. A first heat treatment is carried out to form a first oxide layer over the semiconductor substrate. The first oxide layer includes first and second portions. The first portion is in the first region. The second portion is in the second region. The first portion is thinner than the second portion.

In another embodiment, a method of forming a semiconductor device may include, but is not limited to, the following processes. A first oxide film is formed over first and second regions of a semiconductor substrate. A nitrogen-diffusion region is formed in the first oxide film. The nitrogen-diffusion region and the first oxide film are selectively removed to expose the second region of the semiconductor substrate. The nitrogen-diffusion region and the first oxide film remain in the first region. A heat treatment is carried out to form a second oxide film over the second region of the semiconductor substrate. The second oxide film is thicker than the first oxide film.

In still another embodiment, a method of forming a semiconductor device may include, but is not limited to, the following processes. A semiconductor substrate having first and second shallow regions is prepared. The first shallow region is higher in nitrogen concentration than the second shallow region. The semiconductor substrate is then thermally oxidized.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a fragmentary cross sectional elevation view illustrating a semiconductor device in a step involved in a method of forming the semiconductor device in accordance with a first preferred embodiment of the present invention;

FIG. 1B is a fragmentary cross sectional elevation view illustrating a semiconductor device in a step, subsequent to the step of FIG. 1A, involved in the method of forming the semiconductor device in accordance with the first preferred embodiment of the present invention;

FIG. 1C is a fragmentary cross sectional elevation view illustrating a semiconductor device in a step, subsequent to the step of FIG. 1B, involved in the method of forming the semiconductor device in accordance with the first preferred embodiment of the present invention;

FIG. 1D is a fragmentary cross sectional elevation view illustrating a semiconductor device in a step, subsequent to the step of FIG. 1C, involved in the method of forming the semiconductor device in accordance with the first preferred embodiment of the present invention;

FIG. 1E is a fragmentary cross sectional elevation view illustrating a semiconductor device in a step, subsequent to the step of FIG. 1D, involved in the method of forming the semiconductor device in accordance with the first preferred embodiment of the present invention;

FIG. 1F is a fragmentary cross sectional elevation view illustrating a semiconductor device in a step, subsequent to the step of FIG. 1E, involved in the method of forming the semiconductor device in accordance with the first preferred embodiment of the present invention;

FIG. 1G is a fragmentary cross sectional elevation view illustrating a semiconductor device in a step, subsequent to the step of FIG. 1F, involved in the method of forming the semiconductor device in accordance with the first preferred embodiment of the present invention;

FIG. 1H is a fragmentary cross sectional elevation view illustrating a semiconductor device in a step, subsequent to the step of FIG. 1G, involved in the method of forming the semiconductor device in accordance with the first preferred embodiment of the present invention;

FIG. 1I is a fragmentary cross sectional elevation view illustrating a semiconductor device in a step, subsequent to the step of FIG. 1H, involved in the method of forming the semiconductor device in accordance with the first preferred embodiment of the present invention;

FIG. 1J is a fragmentary cross sectional elevation view illustrating a semiconductor device in a step, subsequent to the step of FIG. 1I, involved in the method of forming the semiconductor device in accordance with the first preferred embodiment of the present invention;

FIG. 2 is a diagram showing a relationship between a thickness of a second thin film portion and an amount of nitrogen in a silicon substrate when an oxidation process is carried out to oxidize a 6.0 nm-thick region of the silicon substrate;

FIG. 3A is a fragmentary cross sectional elevation view illustrating a semiconductor device in a step involved in a method of forming the semiconductor device in accordance with a second preferred embodiment of the present invention;

FIG. 3B is a fragmentary cross sectional elevation view illustrating a semiconductor device in a step, subsequent to the step of FIG. 3A, involved in the method of forming the semiconductor device in accordance with the second preferred embodiment of the present invention;

FIG. 3C is a fragmentary cross sectional elevation view illustrating a semiconductor device in a step, subsequent to the step of FIG. 3B, involved in the method of forming the semiconductor device in accordance with the second preferred embodiment of the present invention;

FIG. 3D is a fragmentary cross sectional elevation view illustrating a semiconductor device in a step, subsequent to the step of FIG. 3C, involved in the method of forming the semiconductor device in accordance with the second preferred embodiment of the present invention;

FIG. 3E is a fragmentary cross sectional elevation view illustrating a semiconductor device in a step, subsequent to the step of FIG. 3D, involved in the method of forming the semiconductor device in accordance with the second preferred embodiment of the present invention;

FIG. 4A is a fragmentary cross sectional elevation view illustrating a semiconductor device in a step involved in a method of forming the semiconductor device in accordance with a third preferred embodiment of the present invention;

FIG. 4B is a fragmentary cross sectional elevation view illustrating a semiconductor device in a step, subsequent to the step of FIG. 4A, involved in the method of forming the semiconductor device in accordance with the third preferred embodiment of the present invention;

FIG. 4C is a fragmentary cross sectional elevation view illustrating a semiconductor device in a step, subsequent to the step of FIG. 4B, involved in the method of forming the semiconductor device in accordance with the third preferred embodiment of the present invention;

FIG. 5A is a fragmentary cross sectional elevation view illustrating a semiconductor device in a step, subsequent to the step of FIG. 4C, involved in the method of forming the semiconductor device in accordance with the third preferred embodiment of the present invention;

FIG. 5B is a fragmentary cross sectional elevation view illustrating a semiconductor device in a step, subsequent to the step of FIG. 5A, involved in the method of forming the semiconductor device in accordance with the third preferred embodiment of the present invention;

FIG. 6 is a diagram showing relationships between a thickness of a fourth thin film portion and nitrogen concentration of a silicon substrate when an oxidation process is carried out to oxidize a 6.0 nm-thick region of the silicon substrate;

FIG. 7A is a fragmentary cross sectional elevation view illustrating a semiconductor device in a step involved in a method of forming the semiconductor device in the related art;

FIG. 7B is a fragmentary cross sectional elevation view illustrating a semiconductor device in a step, subsequent to the step of FIG. 7A, involved in the method of forming the semiconductor device in the related art;

FIG. 7C is a fragmentary cross sectional elevation view illustrating a semiconductor device in a step, subsequent to the step of FIG. 7B, involved in the method of forming the semiconductor device in the related art;

FIG. 7D is a fragmentary cross sectional elevation view illustrating a semiconductor device in a step, subsequent to the step of FIG. 7C, involved in the method of forming the semiconductor device in the related art;

FIG. 7E is a fragmentary cross sectional elevation view illustrating a semiconductor device in a step, subsequent to the step of FIG. 7D, involved in the method of forming the semiconductor device in the related art; and

FIG. 7F is a fragmentary cross sectional elevation view illustrating a semiconductor device in a step, subsequent to the step of FIG. 7E, involved in the method of forming the semiconductor device in the related art.

### DETAILED DESCRIPTION OF THE PREFERRED EMBODIMENTS

Embodiments of the invention will be now described herein with reference to illustrative embodiments. Those skilled in the art will recognize that many alternative embodiments can be accomplished using the teaching of the embodiments of the present invention and that the embodiments of the invention are not limited to the embodiments illustrated for explanatory purpose.

In one embodiment, a method of forming a semiconductor device may include, but is not limited to, the following processes. A nitrogen-diffusion region is selectively formed in a semiconductor substrate having first and second regions. The nitrogen-diffusion region is at a shallow level of the first region. A first heat treatment is carried out to form a first oxide layer over the semiconductor substrate. The first oxide layer includes first and second portions. The first portion is in the first region. The second portion is in the second region. The first portion is thinner than the second portion.

In some cases, the nitrogen-diffusion region may be formed as follows. A second oxide layer is formed over the semiconductor substrate. The second oxide layer has third and fourth portions. The third portion is in the first region. The fourth portion is in the second region. The third portion is thinner than the fourth portion. A nitrogen-introduced region is formed in the third and fourth portions. The nitrogen-introduced region is at a shallow level of the second oxide layer. A second heat treatment is carried out to cause a thermal diffusion of nitrogen from the nitrogen-introduced region through the third portion into the first region to form the nitrogen-diffusion region in the first region. The second oxide layer is removed before carrying out the first heat treatment.

In some cases, the second heat treatment is carried out in an oxygen atmosphere.

In some cases, the second heat treatment is carried out at a temperature in the range of 1000° C. to 11000° C.

In some cases, the nitrogen-introduced region is formed by a plasma nitridation method in the third and fourth portions.

In some cases, the nitrogen-diffusion region may be selectively formed as follows. A second oxide layer is formed over the semiconductor substrate. The second oxide layer has third and fourth portions. The third portion is in the first region. The fourth portion is in the second region. The third portion is thinner than the fourth portion. Nitrogen is introduced through the second oxide layer into the first region of the semiconductor device to form the nitrogen-diffusion region in the first region. The second oxide layer is removed before carrying out the first heat treatment. In some cases, the introduction of nitrogen through the second oxide layer into the first region may be performed by an ion-implantation of nitrogen through the second oxide layer into the first region.

In some cases, the first heat treatment may be carried out by an in-situ stream generation oxidation process at a temperature in the range of 1000° C. to 11000° C.

In some cases, the first heat treatment may be carried out by a wet oxidation process at a temperature in the range of 800° C. to 900° C.

In some cases, the nitrogen-diffusion region has a nitrogen concentration at a depth of 3 nm in the range of 1×10¹⁶ atoms/cm³ to 2×10¹⁷ atoms/cm³.

In some cases, the method may further include, but is not limited to, forming a layered structure over the first and second portions; and patterning the layered structure to form first and second gate insulating films and first and second gate electrodes. The first gate insulating film and the first gate electrode are in the first region. The second gate insulating film and the second gate electrode are in the second region. The first gate insulating film is thinner than the second gate insulating film.

In another embodiment, a method of forming a semiconductor device may include, but is not limited to, the following processes. A first oxide film is formed over first and second regions of a semiconductor substrate. A nitrogen-diffusion region is formed in the first oxide film. The nitrogen-diffusion region and the first oxide film are selectively removed to expose the second region of the semiconductor substrate. The nitrogen-diffusion region and the first oxide film remain in the first region. A heat treatment is carried out to form a second oxide film over the second region of the semiconductor substrate. The second oxide film is thicker than the first oxide film.

In some cases, the nitrogen-diffusion region may be formed by a plasma nitridation method in the third and fourth portions.

In some cases, the method may further include, but is not limited to, forming a layered structure over the first and second portions, and patterning the layered structure to form first and second gate insulating films and first and second gate electrodes. The first gate insulating film and the first gate electrode are in the first region. The second gate insulating film and the second gate electrode are in the second region. The first gate insulating film is thinner than the second gate insulating film.

In still another embodiment, a method of forming a semiconductor device may include, but is not limited to, the following processes. A semiconductor substrate having first and second shallow regions is prepared. The first shallow region is higher in nitrogen concentration than the second shallow region. The semiconductor substrate is then thermally oxidized.

In some cases, thermal oxidization of the first and second shallow regions may be varied out by a first heat treatment to form a first oxide layer over the first and second shallow regions. The first oxide layer includes first and second portions. The first portion is over the first shallow region. The second portion is over the second shallow region. The first portion is thinner than the second portion.

In some cases, the semiconductor substrate may be prepared as follows. A second oxide layer having first and second portions is formed. The first portion is in the first region. The second portion is in the second region. The first portion is thinner than the second portion. Nitrogen is introduced into a shallow region of the first oxide layer. Nitrogen is thermally diffused through the first portion into the first shallow region. The first oxide layer is removed.

In some cases, the semiconductor substrate can be papered as follows. A second oxide layer is formed over the semiconductor substrate. The second oxide layer having third and fourth portions is formed. The third portion is in the first region. The fourth portion is in the second region. The third portion is thinner than the fourth portion. Nitrogen is introduced through the second oxide layer into the first region of the semiconductor device to form the nitrogen-diffusion region in the first region. The second oxide layer is removed before carrying out the first heat treatment.

In some cases, the semiconductor substrate can be papered as follows. A first oxide film is formed over first and second regions of a semiconductor substrate. A nitrogen-diffusion region is formed in the first oxide film. The nitrogen-diffusion region and the first oxide film are selectively removed to expose the second region of the semiconductor substrate. The nitrogen-diffusion region and the first oxide film remain in the first region.

In some cases, the method may further include, but is not limited to, forming a layered structure over the first and second portions, and patterning the layered structure to form first and second gate insulating films and first and second gate electrodes. The first gate insulating film and the first gate electrode are in the first region. The second gate insulating film and the second gate electrode are in the second region. The first gate insulating film is thinner than the second gate insulating film.

### First Embodiment

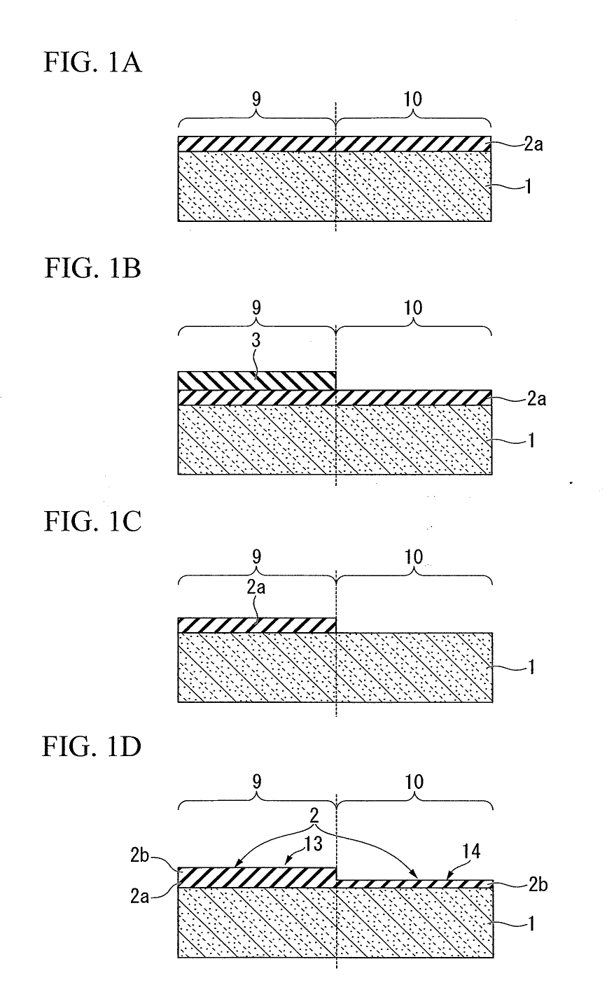

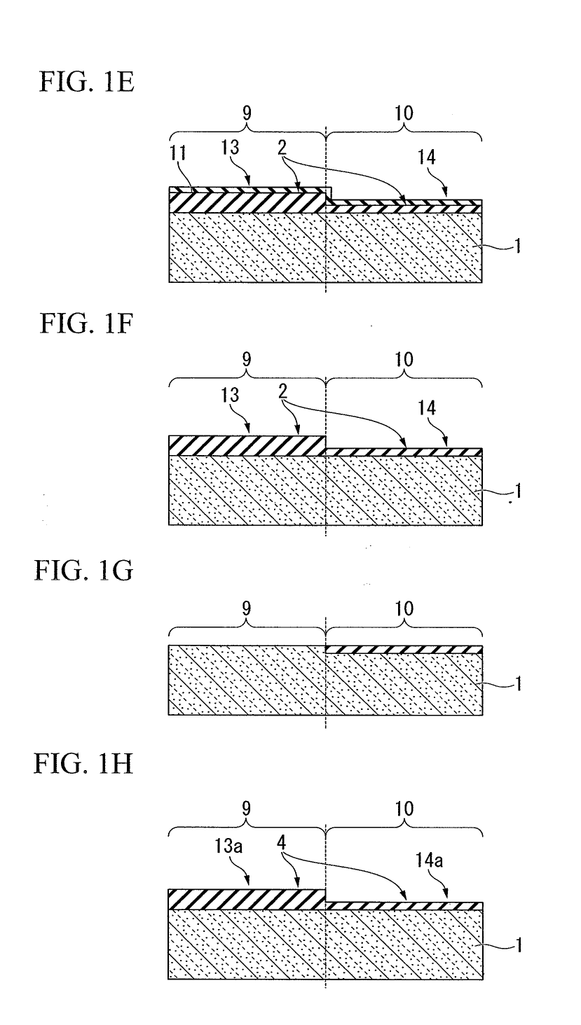

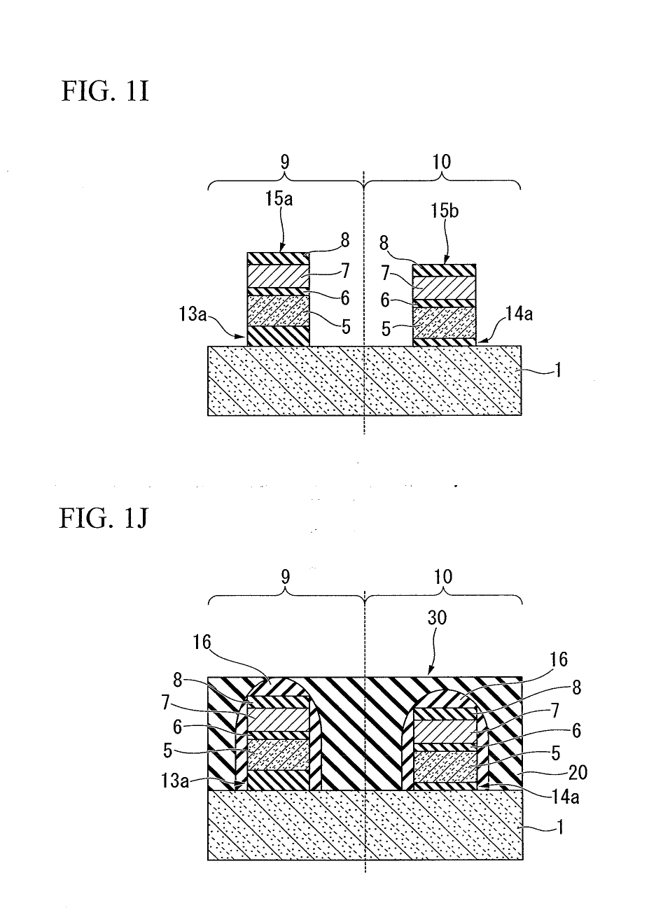

Hereinafter, a method of manufacturing a semiconductor device according to a first embodiment of the invention will be described with reference to FIGS. 1A to 1J. FIGS. 1A to 1J are sectional views showing a method of manufacturing a semiconductor device according to a first embodiment.

A method of manufacturing a semiconductor device 30 according to the first embodiment of the invention may include, but is not limited to, the following processes. A first silicon oxide film 2 is formed on a silicon substrate 1. A nitrogen diffusion region (first silicon nitride region 11) is formed in the first silicon oxide film 2 by a plasma nitridation method. The first silicon oxide film 2 is removed. An in-situ stream generation (ISSG) oxidation process is carried out to form a second silicon oxide film 4 on the silicon substrate 1. According to this embodiment, the process for forming the nitrogen diffusion region (first silicon nitride region 11) can be carried out as follows. For forming the first silicon oxide film 2, a first thick film portion 13 and a first thin film portion 14 are formed in the first silicon oxide film 2. The nitrogen diffusion region (first silicon nitride region 11) is provided in the first thick film portion 13 and the first thin film portion 14. A heat treatment is carried out for the nitrogen diffusion region (first silicon nitride region 11) to diffuse nitrogen atoms into the silicon substrate 1 directly below the first thin film portion 14. Subsequently, the entire first silicon oxide film 2 is removed. The ISSG oxidation is then carried out.

As shown in FIG. 1A, a first layer 2a for a first silicon oxide film is formed on the entire surface of the silicon substrate 1 by a thermal oxidation treatment. In this case, the thermal oxidation treatment may be preferably radical oxidation (ISSG: In-Situ Steam Generation). At this time, the thermal oxidation treatment is carried out at the heating temperature of 1050° C.

As shown in FIG. 1B, photoresist 3 is formed. The photoresist 3 is applied onto the first layer 2a for a first silicon oxide film. The photoresist 3 is patterned. Thus, the photoresist 3 covers only a thick film portion region 9 on the first layer 2a for a first silicon oxide film and exposes a thin film portion region 10 on the first layer 2a for a first silicon oxide film.

A wet etching process is carried out for the first layer 2a for a first silicon oxide film with the photoresist 3 as a mask. Thus, the first layer 2a for a first silicon oxide film in the thin film portion region 10 is removed. A chemical for wet etching may be preferably buffered hydrofluoric acid (a mixture of hydrofluoric acid and ammonium fluoride). Further, wet etching causes side-etch at the first layer 2a for a first silicon oxide film in the thick film portion region 9. For this reason, it is preferable to adjust the opening area of the photoresist 3 to be small by the amount of side-etch in advance. Thereafter, the photoresist 3 is separated from the first layer 2a for a first silicon oxide film. FIG. 1C shows a state where the photoresist 3 is separated from the first layer 2a for a first silicon oxide film in the thick film portion region 9.

As shown in FIG. 1D, a second thermal oxidation treatment is carried out. For carrying out the second thermal oxidation treatment, foreign substances are removed from the silicon substrate 1 in the thin film portion region 10 and from the first silicon oxide layer 2a for a first silicon oxide film in the thick film portion region 9. The removal can be carried out by a lift-off (cleaning) process using ammonia hydrogen peroxide water. This cleaning process will decrease the thickness of the first layer 2a for a first silicon oxide film in the thick film portion region 9.

The second thermal oxidation treatment is carried out to form a second layer 2b for a first silicon oxide film on the silicon substrate 1 in the thin film portion region 10 and on the first layer 2a for a first silicon oxide film in the thick film portion region 9. Thus, the first silicon oxide film 2 is formed which includes the first layer 2a for a first silicon oxide film and the second layer 2b for a first silicon oxide film. The first silicon oxide film 2 includes a first thick film portion 13 which includes the stack of the first layer 2a for a first silicon oxide film and the second layer 2b for a first silicon oxide film in the thick film portion region 9, and a first thin film portion 14 which is formed only by the second layer 2b for a first silicon oxide film in the thin film portion region 10.

At this time, the first thin film portion 14 may preferably have a thickness of 1 to 3 nm. The second thermal oxidation treatment method may preferably be a dry oxidation process. The second thermal oxidation treatment method may preferably be carried out at a heating temperature of 900° C.

As shown in FIG. 1E, the nitrogen diffusion region (first silicon nitride region 11) is provided in the first thick film portion 13 and the first thin film portion 14. First, the surface of the first thick film portion 13 and the surface of the first thin film portion 14 are nitrided by the plasma nitridation method. With this nitridation, the first silicon nitride region 11 containing nitrogen of 5.94×10¹⁸ atoms/cm³ to 1.25×10²° atoms/cm³ is formed on the surface of the first thin film portion 14 and the first thick film portion 13. The content of nitrogen by plasma nitridation may be in a range of 1×10¹⁶/cm² to 2×10¹⁷/cm² at a depth of 3 nm from the surface of the silicon substrate 1.

As shown in FIG. 1F, a heat treatment is carried out for the first silicon nitride region 11. This heat treatment diffuses nitrogen atoms from the first silicon nitride region 11 into the silicon substrate 1 directly below the first thin film portion 14. The heat treatment is carried out under an oxygen atmosphere at a temperature of 1000° C. to 1100° C. The heat treatment causes nitrogen atoms in the first silicon nitride region 11 to be diffused at a depth of 3 nm from the surface of the silicon substrate 1 directly below the first thin film portion 14 at a concentration of 5.94×10¹⁸ atoms/cm³ to 1.25×10²° atoms/cm³.

At this time, the nitrogen atoms in the first silicon nitride region 11 are not diffused into the silicon substrate 1 directly below the first thick film portion 13 and remain in the first thick film portion 13. If the thickness of the first thin film portion 14 is equal to or greater than 3 nm, even when the heat treatment is carried out, nitrogen in the first silicon nitride region 11 is not diffused into the silicon substrate 1 and remains in the first thin film portion 14. If the thickness of the first thin film portion 14 is equal to or smaller than 1 nm, it is difficult to secure in-plane uniformity of the first thin film portion 14. For this reason, the thickness of the first thin film portion 14 may preferably be in a range of 1 to 3 nm.

The heat treatment of the first silicon nitride region 11 may be preferably carried out under an oxygen atmosphere. This is because the amount of diffusion of nitrogen from the first silicon nitride region 11 increases about three times under the oxygen atmosphere rather than under a nitrogen atmosphere. During the heat treatment, pressure under the oxygen atmosphere may be preferably in a range of 1 to 100 torr. The heat treatment is carried out at pressure of 1 to 100 ton under the oxygen atmosphere, such that changes in the thickness of the first silicon oxide film 2 can be prevented.

As shown in FIG. 1G, the first silicon oxide film 2 is removed. The first silicon nitride region 11 is removed by hot phosphoric acid. The first silicon oxide film 2 is removed by wet etching using hydrofluoric acid. If the first silicon oxide film 2 is removed, the surface of the silicon substrate 1 is exposed. The nitrogen atoms are diffused into the surface of the silicon substrate 1 in the thin film portion region 10 at a concentration of 5.94×10¹⁸ atoms/cm³ to 1.25×10²⁰ atoms/cm³. Further, the nitrogen atoms are diffused at a depth of 3 nm from the surface of the silicon substrate 1 in the thin film portion region 10.

At this time, the amount of diffusion of nitrogen elements from the first silicon nitride region 11 into the silicon substrate 1 is controlled by adjusting the process conditions. Specifically, the process conditions include the difference in thickness between the first thick film portion 13 and the first thin film portion 14, the nitrogen concentration, and the temperature, time, pressure, and gas type for a heat treatment after nitridation, and the like. The process conditions may be adjusted in accordance with the amount of nitrogen atoms which will be diffused at a depth of 3 nm from the surface of the silicon substrate 1. With regard to management of the amount of nitrogen atoms in the silicon substrate 1, for example, direct measurement may be preferably carried out by using an X-ray photoelectron spectroscopy (XPS). The measurement is carried out before a second silicon oxide film 4 which will be described below is formed on the silicon substrate 1.

As shown in FIG. 1H, a third thermal oxidation treatment is carried out to form a second silicon oxide film 4. This thermal oxidation treatment is carried out by ISSG oxidation at a temperature of 1000 to 1100° C. The thermal oxidation treatment may be carried out by wet oxidation process at a temperature of 800° C. to 900° C.

While the second silicon oxide film 4 is grown on the silicon substrate 1 by the third thermal oxidation treatment, the growing rate of the silicon oxide film is reduced in the thin film portion region 10 where the nitrogen atoms are diffused into the silicon substrate 1 rather than in the thick film portion region 9 where the nitrogen atoms are not diffused. Thus, the thickness of the second thick film portion 13a formed by the second silicon oxide film 4 in the thick film portion region 9 increases, and the thickness of the second thin film portion 14a formed by the second silicon oxide film 4 in the thin film portion region 10 decreases. In this way, the second thick film portion 13a and the second thin film portion 14a having different thicknesses are formed in the second silicon oxide film 4.

At this time, the thickness of the second thin film portion 14a depends on the amount of nitrogen at a depth of 3 nm from the surface of the silicon substrate 1. If the amount of nitrogen is great, the thickness of the second thin film portion 14a decreases, and if the amount of nitrogen is small, the thickness of the second thin film portion 14a increases. The thickness of the second thin film portion 14a can be controlled by controlling the amount of nitrogen of the silicon substrate 1 in the thin film portion region 10.

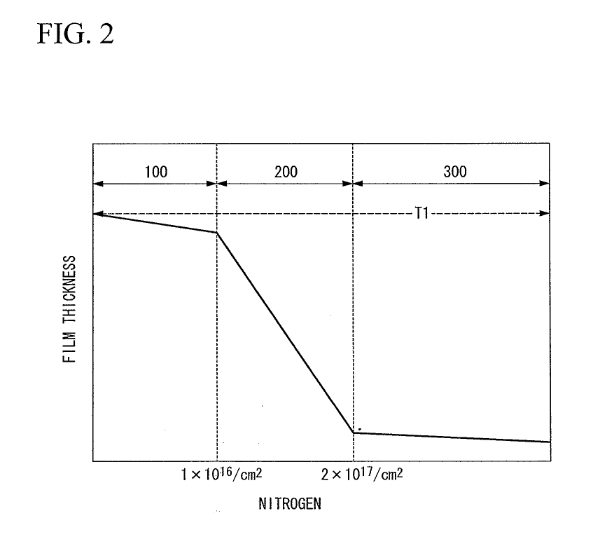

FIG. 2 shows the relationship between the thickness of the second thin film portion 14a and the amount of nitrogen of the silicon substrate 1 when an oxidation process is carried out to oxidize a 6.0 nm-thick region of the silicon substrate 1. The relationship between the thickness of the second thin film portion 14a and the amount of nitrogen of the silicon substrate 1 shown in FIG. 2 is divided into the following three regions 100, 200 and 300.

In a region 100, the nitrogen concentration at a depth of 3 nm from the surface of the silicon substrate 1 is in a range of 0/cm² to 1×10¹⁶/cm². The thickness of the second thin film portion 14a little depends on the amount of nitrogen of the silicon substrate 1 and is substantially the same as when the amount of nitrogen of the silicon substrate 1 is zero. In the region 100, the nitrogen atoms of the silicon substrate 1 are mostly diffused by a heat treatment before the third thermal oxidation treatment. For this reason, it is difficult to differentiate the thicknesses of the second thick film portion 13a and the second thin film portion 14a.

In a region 300, the nitrogen concentration at a depth of 3 nm from the surface of the silicon substrate 1 is equal to or greater than 2×10¹⁷/cm². Similarly to the region 100, the thickness of the second thin film portion 14a little depends on the amount of nitrogen of the silicon substrate 1. However, within the range of the region 300, the thickness of the second thin film portion 14a is small compared to when the amount of nitrogen of the silicon substrate 1 is zero. Further, in the region 300, even after the third thermal oxidation treatment has been carried out, nitrogen remains in the silicon substrate 1. For this reason, it is difficult to differentiate the thicknesses of the second thick film portion 13a and the second thin film portion 14a. In addition, it is a concern that the nitrogen atoms remaining in the silicon substrate 1 may adversely affect the device characteristics.

A region 200 has the nitrogen concentration of 1×10¹⁶/cm² to 2×10¹⁷/cm² at a depth of 3 nm from the surface of the silicon substrate 1. In the region 200, the thickness of the second thin film portion 14a significantly depends on the amount of nitrogen of the silicon substrate 1. For this reason, the amount of nitrogen of the silicon substrate 1 may be preferably determined within the range of the region 200.

The oxidation condition when the third thermal oxidation treatment is carried out under the condition of the region 200 may be preferably, for example, the ISSG at the heating temperature of 1000° C. to 1100° C. To secure the difference in thickness, a wet oxidation process at a temperature of 800° C. to 900° C. may be carried out. This is because, in the wet oxidation process, the thickness may significantly depend on the amount of nitrogen.

As shown in FIG. 1I, a first gate electrode 15a and a second gate electrode 15b are formed. A polysilicon film 5, a tungsten silicide film 6, a tungsten film 7, and a second silicon nitride film 8 are sequentially stacked on the second thick film portion 13a and the second thin film portion 14a. A lithography process and a dry etching process are carried out. Thus, the first gate electrode 15a and the second gate electrode 15b are formed. Since the second thick film portion 13a and the second thin film portion 14a are different in thickness, the first gate electrode 15a and the second gate electrode 15b are formed to be different in height.

As shown in FIG. 1J, a gate insulating film 20 is formed. First, a silicon nitride film 16 is formed on the second silicon nitride film 8. The silicon nitride 16 covers the side surfaces of the polysilicon film 5, the tungsten silicide film 6, and the tungsten film 7 by etch-back. The first gate electrode 15a and the second gate electrode 15b are buried by an insulating film (not shown). The surface of the insulating film (not shown) is planarized by CMP (Chemical Mechanical Polishing) to form the gate insulating film 20. Thereafter, the process progresses to a bit line forming step, such that the semiconductor device 30 of the first embodiment is completed. Although in this embodiment, the process is constructed on the premise of multi-oxide, triple-oxide may be formed by the same manufacturing method.

According to the manufacturing method of this embodiment, before the first silicon oxide film 2 is formed, the first silicon oxide film 2 is removed. For this reason, the second silicon oxide film 4 is formed, while the silicon substrate 1 is exposed in the thick film portion region 9 and the thin film portion region 10. Thus, before the second silicon oxide film 4 is formed, there is no effect of removing the first silicon oxide film 2 by cleaning using ammonia hydrogen peroxide water. Further, there is no effect of film quality deterioration by the first thermal oxidation treatment and the second thermal oxidation treatment.

The second thick film portion 13a and the second thin film portion 14a having different thicknesses can be formed by the single thermal oxidation treatment. For this reason, variations in the thickness of the second thick film portion 13a and the second thin film portion 14a can be reduced within ±0.4 nm. Since the thickness of the second thin film portion 14a depends on the amount of nitrogen diffused into the silicon substrate 1, thickness control is required by controlling nitrogen diffusion into the silicon substrate 1. By controlling the amount of nitrogen, it is possible to differentiate the thickness of the second thick film portion 13a and the thickness of the second thin film portion 14a. The amount of diffusion of nitrogen from the first silicon nitride region 11 into the silicon substrate 1 can be controlled by the thickness of the first thin film portion 14. Further, the amount of diffusion of nitrogen from the first silicon nitride region 11 into the silicon substrate 1 can be sufficiently controlled by the thickness of the second thin film portion 14a. In addition, the amount of diffusion of nitrogen into the silicon substrate 1 can be controlled by the nitrogen concentration and the temperature, time, pressure, and gas type for a heat treatment after nitridation. In this embodiment, the second thick film portion 13a can be formed as a single-layered film. For this reason, it is possible to solve the problems regarding control of the thickness of the second thick film portion 13a and securing reliability in the related art. Thus, a high-reliable semiconductor device 30 can be provided.

### Second Embodiment

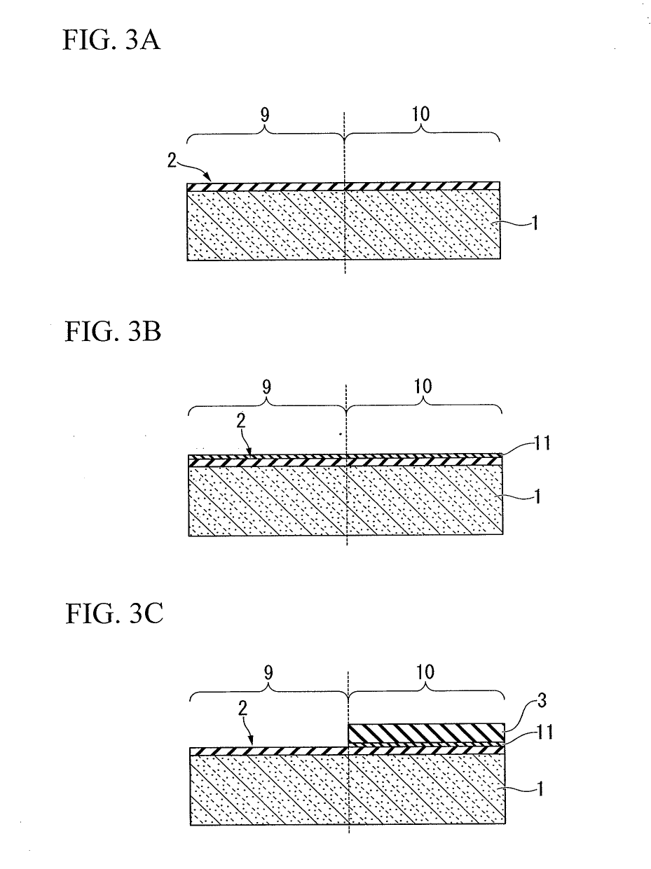

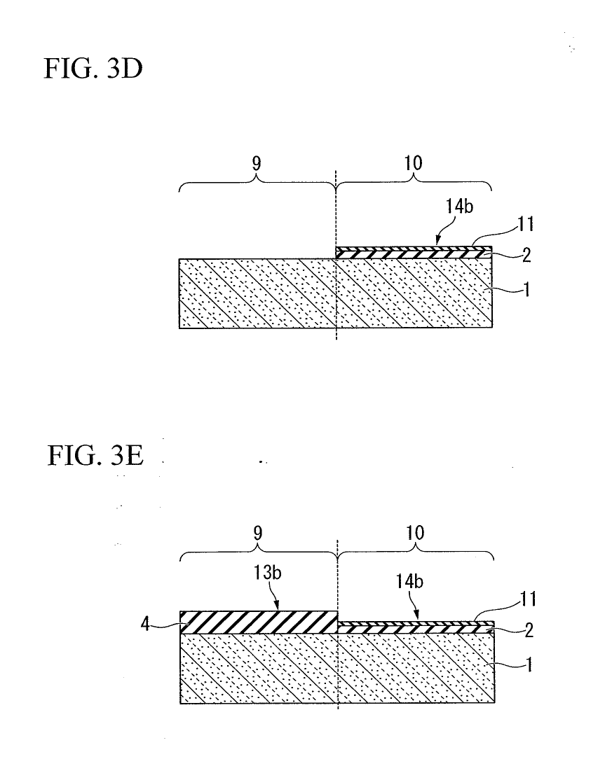

Hereinafter, a method of manufacturing a semiconductor device 30 according to a second embodiment of the invention will be described with reference to FIGS. 3A to 3E. FIGS. 3A to 3E are sectional views showing a method of manufacturing a semiconductor device 30 according to a second embodiment.

A method of manufacturing a semiconductor device 30 according to the second embodiment of the invention includes the following processes. A first silicon oxide film 2 is formed on a silicon substrate 1. A nitrogen diffusion region (first silicon nitride region 11) is formed in the entire first silicon oxide film 2 by using a plasma nitridation method. Part of the first silicon oxide film 2 is removed. The ISSG oxidation is carried to form a second silicon oxide film 4 on the silicon substrate 1 to be thicker than the first silicon oxide film 2.

FIG. 3A is a sectional view after a first silicon oxidation treatment. First, a first thermal oxidation treatment is carried out to form the first silicon oxide film 2 on the entire surface of the silicon substrate 1. The thermal oxidation treatment may be preferably radical oxidation (ISSG: In-Situ Steam Generation). The thermal oxidation treatment is carried out at the heating temperature of 1050° C.

As shown in FIG. 3B, the nitrogen diffusion region (first silicon nitride region 11) is provided in the first silicon oxide film 2. First, the surface of the first silicon oxide film 2 is nitrided by a plasma nitridation method. With this nitridation, the first silicon nitride region 11 containing nitrogen of 5.94×10¹⁸ atoms/cm³ to 1.25×10²° atoms/cm³ is formed on the surface of the first silicon oxide film 2.

As shown in FIG. 3C, photoresist 3 is formed. First, the photoresist 3 is applied onto the first silicon nitride region 11. The photoresist 3 is patterned. Thus, the photoresist 3 covers only the thick film portion region 9 on the first silicon nitride region 11 and exposes a first silicon nitride region 11 in the thin film portion region 10.

A wet etching process is carried out using hot phosphoric acid with the photoresist 3 as a mask. The wet etching process is carried out to etch the first silicon nitride region 11. Thus, the first silicon nitride region 11 in the thick film portion region 9 is removed, and the first silicon oxide film 2 in the thick film portion region 9 is exposed. At this time, the wet etching process will cause side-etch in the remaining first silicon nitride region 11. For this reason, it is preferable to adjust the opening area of the photoresist 3 to be small by the amount of side-etch in advance.

The first silicon oxide film 2 in the thick film portion region 9 is removed by a wet etching process using hydrofluoric acid with the photoresist 3 as a mask. Thus, the silicon substrate 1 is exposed only in the thick film portion region 9. Thereafter, the photoresist 3 is separated from the first silicon nitride region 11 in the thin film portion region 10. In this way, a third thin film portion 14b which includes the stack of the first silicon oxide film 2 and the first silicon nitride region 11 remains in the thin film portion region 10. This state is shown in FIG. 3D.

As shown in FIG. 3E, the second silicon oxide film 4 is formed on the silicon substrate 1 in the thick film portion region 9. First, a second thermal oxidation treatment is carried out on the silicon substrate 1 to form the second silicon oxide film 4 on the silicon substrate 1 in the thick film portion region 9 to be thicker than the third thin film portion 14b. Since the first silicon nitride region 11 is present on the surface of the third thin film portion 14b, oxidation reaction of the third thin film portion 14b does not progress. For this reason, the thickness of the third thin film portion 14b does not change before the second thermal oxidation treatment. The second thermal oxidation treatment method may be preferably the ISSG oxidation at a temperature of 900° C.

Similarly to the first embodiment, a first gate electrode 15a and a second gate electrode 15b are formed. First, polysilicon film 5, tungsten silicide film 6, tungsten film 7, and a second silicon nitride film 8 are sequentially laminated on the third thick film portion 13b and the third thin film portion 14b. A lithography process and a dry etching process are carried out. Thus, the first gate electrode 15a and the second gate electrode 15b are formed. Since the third thick film portion 13b and the third thin film portion 14b are different in thickness, thus the first gate electrode 15a and the second gate electrode 15b are formed to be different in height. The subsequent process is the same as in the manufacturing method of the first embodiment, thus description thereof will be omitted.

According to this embodiment, before the third thick film portion 13b is formed, the first silicon oxide film 2 is removed. For this reason, when the third thick film portion 13b is formed, the silicon substrate 1 in the thick film portion region 9 is exposed, such that the third thick film portion 13b can be formed as a single-layered film.

While the silicon substrate 1 in the thick film portion region 9 has a usual oxidation rate, the oxidation rate of the first silicon nitride region 11 in the thin film portion region 10 can be reduced. Thus, the third thick film portion 13b can be formed at a thickness corresponding to the second silicon oxide film 4, and the third thin film portion 14b can be formed at the thickness of the first silicon oxide film 2. For this reason, it is easy to set the thickness of the third thick film portion 13b and the thickness of the third thin film portion 14b together. Thus, when the condition of oxide film reliability or thickness limitation of the third thick film portion 13b is strict, this embodiment is particularly effective. By controlling the thickness of the first silicon oxide film 2 and the amount of nitrogen of the first silicon nitride region 11, it is possible to differentiate the thickness of the second thick film portion 13a and the thickness of the second thin film portion 14a.

### Third Embodiment

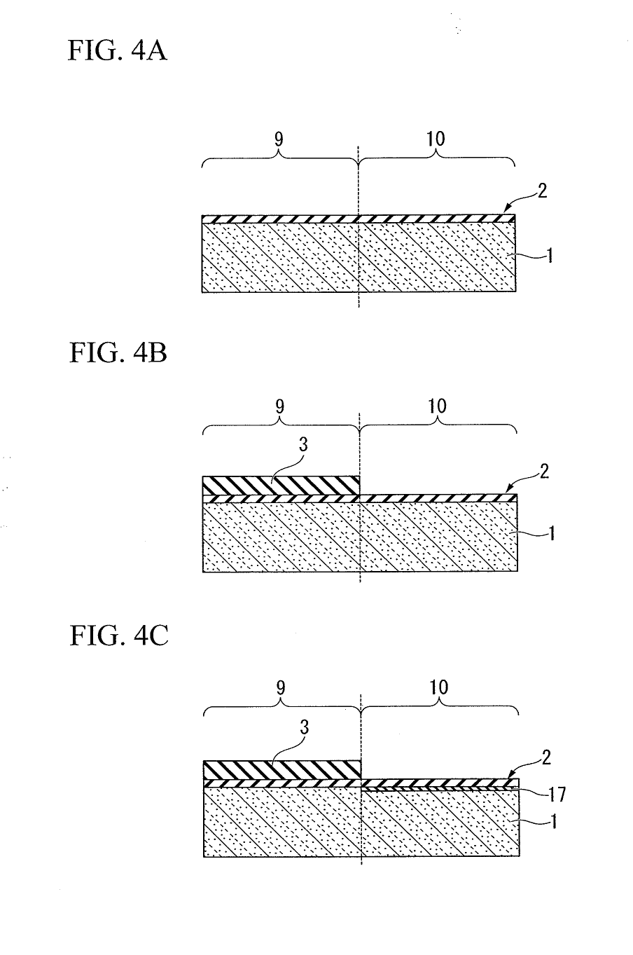

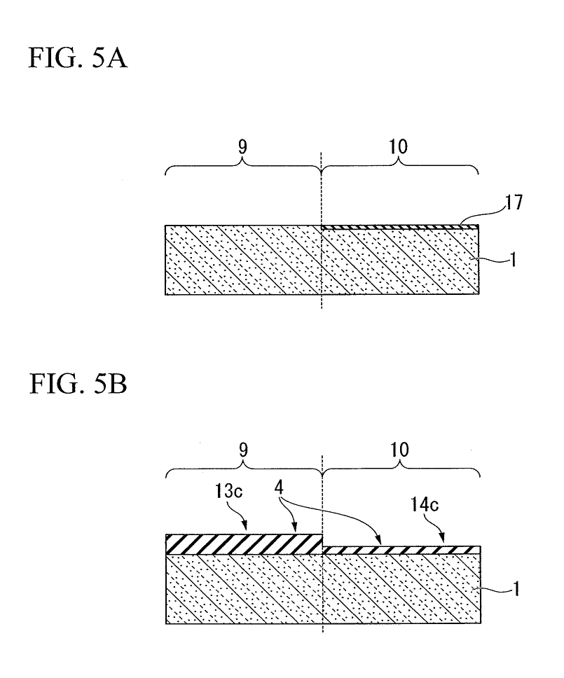

Hereinafter, a method of manufacturing a semiconductor device 30 according to a third embodiment of the invention will be described with reference to FIGS. 4A to 4C and FIGS. 5A and 5B. FIGS. 4A to 4C and FIGS. 5A and 5B are sectional views showing a method of manufacturing a semiconductor device 30 according to a third embodiment.

A method of manufacturing a semiconductor device 30 according to the third embodiment of the invention may include the following processes. A first silicon oxide film 2 is formed on a silicon substrate 1. A nitrogen diffusion region 17 is formed by ion implantation into part of the silicon substrate 1 through the first silicon oxide film 2. The first silicon oxide film 2 is removed. An ISSG oxidation process is carried out to form a second silicon oxide film 4 on the silicon substrate 1.

As shown in FIG. 4A, the first silicon oxide film 2 is formed on the entire surface of the silicon substrate 1 by a thermal oxidation treatment. In this case, the thermal oxidation treatment may be preferably radical oxidation (ISSG: In-Situ Steam Generation). The thermal oxidation treatment is carried out at the heating temperature of 1050° C.

As shown in FIG. 4B, photoresist 3 is formed. First, the photoresist 3 is applied onto the first silicon oxide film 2. The photoresist 3 is patterned. Thus, the photoresist 3 covers only the thick film portion region 9 on the first silicon oxide film 2 and exposes the first silicon oxide film 2 in the thin film portion region 10.

As shown in FIG. 4C, the nitrogen diffusion region 17 is provided at a part of the silicon substrate 1. First, nitrogen is implanted into the first silicon oxide film 2 in the thin film portion region 10 by ion implantation with the photoresist 3 as a mask. Thus, the nitrogen diffusion region 17 is provided in the silicon substrate 1 corresponding to the thin film portion region 10 through the first silicon oxide film 2. At this time, by using the silicon oxide film 2 as a sacrificing film for ion implantation, damage on the surface of the silicon substrate 1 due to ion implantation is reduced. The ion implantation conditions are adjusted such that the nitrogen concentration in the silicon substrate 1 (at a depth 3 nm from the surface) is in a range of 5.94×10¹⁸ atoms/cm³ to 1.25×10²° atoms/cm³.

The photoresist 3 and the first silicon oxide film 2 are separated from the silicon substrate 1. First, the photoresist 3 is separated from the first silicon oxide film 2. The first silicon oxide film 2 is removed by wet etching using hydrofluoric acid. Thus, the silicon substrate 1 is exposed. FIG. 5A shows a state where the photoresist 3 and the first silicon oxide film 2 are separated from the silicon substrate 1.

As shown in FIG. 5B, a second thermal oxidation treatment is carried out. With regard to the second thermal oxidation treatment, an ISSG oxidation process is carried out at a temperature of 900° C. The second silicon oxide film 4 is grown on the silicon substrate 1 by the second thermal oxidation treatment, in the thin film portion region 10. The nitrogen diffusion region 17 is formed in the silicon substrate 1. Thus, the growing rate of the silicon oxide film is reduced compared to the thick film portion region 9 where no nitrogen diffusion region 17 is formed. Thus, there increases the thickness of a fourth thick film portion 13c formed by the second silicon oxide film 4 in the thick film portion region 9. There decreases the thickness of a fourth thin film portion 14c formed by the second silicon oxide film 4 in the thin film portion region 10. In this way, the fourth thick film portion 13c and the fourth thin film portion 14c having different thicknesses are formed in the second silicon oxide film 4.

The thickness of the fourth thin film portion 14c depends on the amount of nitrogen at a depth of 3 nm from the surface of the silicon substrate 1. If the amount of nitrogen is great, the thickness of the fourth thin film portion 14c decreases. If the amount of nitrogen is small, the thickness of the fourth thin film portion 14c increases. For this reason, by controlling the amount of nitrogen of the silicon substrate 1 in the thin film portion region 10, the thickness of the fourth thin film portion 14c is controlled.

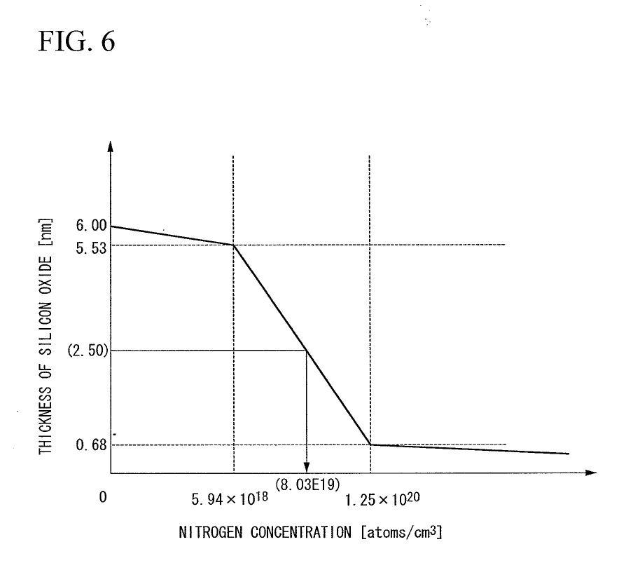

FIG. 6 shows the relationships between the thickness of the fourth thin film portion 14c and the nitrogen concentration of the silicon substrate 1 when an oxidation process is carried out to oxidize a 6.0 nm-thick region of the silicon substrate 1. The relationship between the thickness of the fourth thin film portion 14c and the nitrogen concentration of the silicon substrate 1 shown in FIG. 6 may include the following three divided regions.

In a region where the nitrogen concentration of the silicon substrate 1 is in a range of 0 atoms/cm³ to 5.94×10¹⁸ atoms/cm³, the thickness of the fourth thin film portion 14c little depends on the amount of nitrogen of the silicon substrate 1. When the nitrogen concentration of the silicon substrate 1 is 0 atoms/cm³, the thickness of the fourth thin film portion 14c is substantially identical. In a region where the nitrogen concentration of the silicon substrate 1 is in a range of 0 atoms/cm³ to 5.94×10¹⁸ atoms/cm³, nitrogen of the silicon substrate 1 is mostly diffused by the second thermal oxidation treatment. For this reason, it is difficult to differentiate the thicknesses of the fourth thick film portion 13c and the fourth thin film portion 14c in this embodiment.

In a region where the nitrogen concentration of the silicon substrate 1 is equal to or higher than 1.25×10²° atoms/cm³, the thickness of the fourth thin film portion 14c little depends on the nitrogen concentration of the silicon substrate 1. The thickness of the fourth thin film portion 14c decreases compared to when the nitrogen concentration of the silicon substrate 1 is 0 atoms/cm³. The nitrogen concentration of the silicon substrate 1 is high. Even after the second thermal oxidation treatment has been carried out, nitrogen remains in the silicon substrate 1. For this reason, it is difficult to differentiate the thicknesses of the fourth thick film portion 13c and the fourth thin film portion 14c. Further, it is a concern that the nitrogen atoms remaining in the silicon substrate 1 may adversely affect the device characteristics subsequently.

In a region where the nitrogen concentration of the silicon substrate 1 is in a range of 5.94×10¹⁸ atoms/cm³ to 1.25×10²° atoms/cm³, the thickness of the oxide film of the fourth thin film portion 14c significantly depends on the nitrogen concentration. The thickness of the oxide film of the fourth thin film portion 14c rapidly decreases as the nitrogen concentration of the silicon substrate 1 increases. For this reason, the nitrogen concentration of the silicon substrate 1 in the thin film portion region 10 may be preferably set in a range of 5.94×10¹⁸ atoms/cm³ to 1.25×10²° atoms/cm³.

Similarly to the first embodiment, a first gate electrode 15a and a second gate electrode 15b are formed. A polysilicon film 5, a tungsten silicide film 6, a tungsten film 7, and a second silicon nitride film 8 are sequentially laminated on the fourth thick film portion 13c and the fourth thin film portion 14c. A lithography process and a dry etching process are carried out to form the first gate electrode 15a and the second gate electrode 15b. Since the second thick film portion 13a and the second thin film portion 14a are different in thickness, the first gate electrode 15a and the second gate electrode 15b are different in height. The subsequent process is the same as that in the manufacturing method of the first embodiment, thus description thereof will be omitted.

According to the manufacturing method of this embodiment, nitrogen is directly ion-implanted into the silicon substrate 1 to form the nitrogen diffusion region 17. Since the nitrogen diffusion region 17 is formed by using an ion implantation process, not thermal diffusion, no heat treatment is required. For this reason, the process in the manufacturing method of the semiconductor device 30 can be simplified compared to the method of the first embodiment. Meanwhile, in any semiconductor device 30, damage (defective crystallization) on the silicon substrate 1 is a concern at the time of ion implantation. In such a case, from a viewpoint of correction of damage, a heat treatment may be carried out before the second thermal oxidation treatment is carried out. Further, since the fourth thick film portion 13c and the fourth thin film portion 14c are formed by a single oxidation process, variations in thickness can be reduced.

### Comparative Embodiment

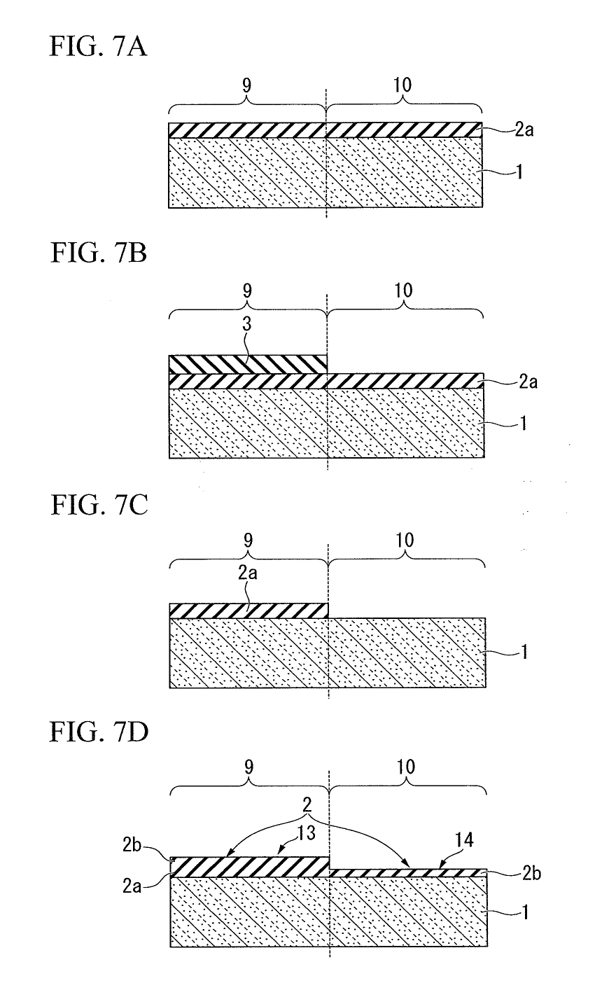

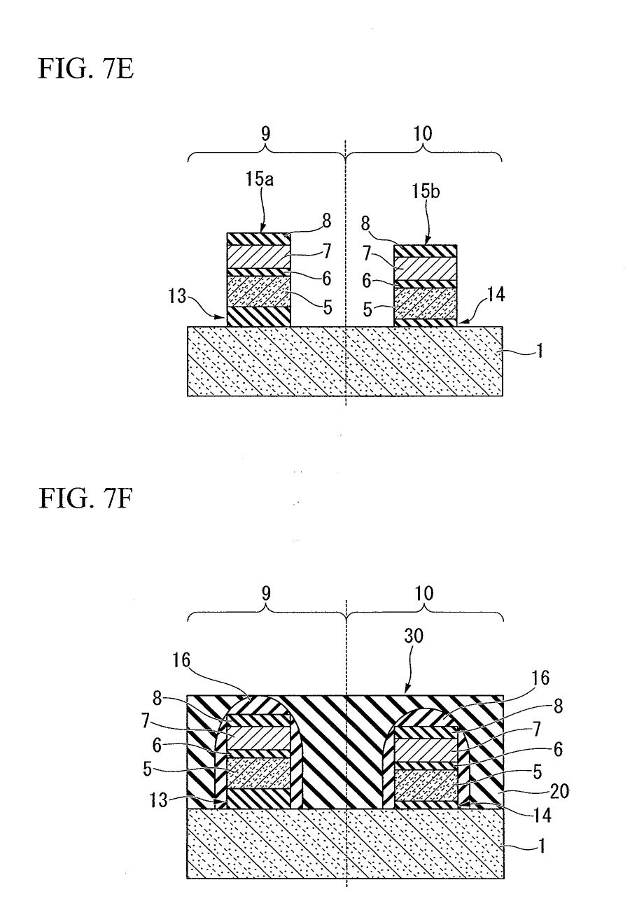

Hereinafter, the differences from an example of the related art will be described for comparison. FIGS. 7A to 7F are sectional views showing a method of manufacturing a semiconductor device 30 according to an example of the related art.

A method of manufacturing a semiconductor device 30 of the related art is the same as the first embodiment of the invention until the first silicon oxide film 2 is formed on the silicon substrate 1, and the first thick film portion 13 and the first thin film portion 14 are provided. The method of the related art is different from the first embodiment of the invention as follows. The method of the related art does not include, after the first silicon oxide film 2 has been formed, the steps of providing the nitrogen diffusion region (first silicon nitride film 11) in the first thick film portion 13 and the first thin film portion 14, and forming the second silicon oxide film 4.

As shown in FIG. 7A, a first layer 2a for a first silicon oxide film is formed on the entire surface of a silicon substrate 1 by a thermal oxidation treatment. As shown in FIG. 7B, photoresist 3 is formed to cover only the thick film portion region 9 on the first layer 2a for a first silicon oxide film. A wet etching process is carried out on the first layer 2a for a first silicon oxide film with the photoresist 3 as a mask to remove the first layer 2a for a first silicon oxide film of the thin film portion region 10. Thereafter, the photoresist 3 is separated from the first layer 2a for a first silicon oxide film. FIG. 7C shows a state where the photoresist 3 is separated from the first layer 2a for a first silicon oxide film of the thick film portion region 9.

A second thermal oxidation treatment is carried out. As a pretreatment, foreign substances on the silicon substrate 1 in the thin film portion region 10 and the first layer 2a for a first silicon oxide film in the thick film portion region 9 by lift-off (cleaning) using ammonia hydrogen peroxide water. This cleaning causes a decrease in the thickness of the first layer 2a for a first silicon oxide film in the thick film portion region 9. A second thermal oxidation treatment is carried out to form a second layer 2b for a first silicon oxide film on the silicon substrate 1 in the thin film portion region 10 and the first layer 2a for a first silicon oxide film in the thick film portion region 9. Thus, the first silicon oxide film 2 is formed which includes the first layer 2a for a first silicon oxide film and the second layer 2b for a first silicon oxide film. The first silicon oxide film 2 includes a first thick film portion 13 which includes the stack of the first layer 2a for a first silicon oxide film and the second layer 2b for a first silicon oxide film in the thick film portion region 9, and a first thin film portion 14 which is formed only by the second layer 2b for a first silicon oxide film in the thin film portion region 10. The thickness of the first thick film portion 13 has a variation of ±0.6 nm. FIG. 7D shows a state where the first silicon oxide film 2 is formed.

As shown in FIG. 7E, a first gate electrode 15a and a second gate electrode 15b are formed. First, a polysilicon film 5, a tungsten silicide film 6, a tungsten film 7, and a second silicon nitride film 8 are sequentially laminated on the first thick film portion 13 and the first thin film portion 14. A lithography process and a dry etching process are carried out. Thus, the first gate electrode 15a and the second gate electrode 15b are formed. Since the second thick film portion 13a and the second thin film portion 14a are different in thickness, the first gate electrode 15a and the second gate electrode 15b are different in height. Subsequently, similarly to the first embodiment, a gate insulating film 20 is formed, such that, as shown in FIG. 7F, the semiconductor device 30 according to the embodiment of the related art is completed.

In the embodiment of the related art, the first thick film portion 13 undergoes the oxidation process two times. For this reason, securing reliability of the first thick film portion 13 is problematic. Further, the first layer 2a for a first silicon oxide film is removed due to cleaning as a pretreatment of the second thermal oxidation treatment. As a result, the thickness of the first thick film portion 13 has a variation of ±0.6 nm, and thickness control is problematic.

### EXAMPLES

Hereinafter, although the invention will be described on the basis of examples, the invention is not limited to the examples.

### Example 1

Hereinafter, an example of the first embodiment will be described. As shown in FIG. 1A, the first layer 2a for a first silicon oxide film having a thickness of 5.3 nm was formed on the silicon substrate 1 by the first thermal oxidation treatment. In this case, with regard to the thermal oxidation treatment, radical oxidation (ISSG: In-Situ Steam Generation) was used. The thermal oxidation treatment was carried out at the heating temperature of 1050° C.

As shown in FIG. 1B, the photoresist 3 was formed. The photoresist 3 was formed to cover the thick film portion region 9 on the first layer 2a for a first silicon oxide film and also to expose the thin film portion region 10 on the first layer 2a for a first silicon oxide film.

The first layer 2a for a first silicon oxide film on the thin film portion region 10 was removed by wet etching with the photoresist 3 as a mask. As the chemical for wet etching, buffered hydrofluoric acid (a mixture of hydrofluoric acid and ammonium fluoride) was used. Thereafter, the photoresist 3 was separated from the first layer 2a for a first silicon oxide film.

As the pretreatment of the second thermal oxidation treatment, foreign substances on the silicon substrate 1 in the thin film portion region 10 and the first layer 2a for a first silicon oxide film in the thick film portion region 9 was removed by lift-off (cleaning) using ammonia hydrogen peroxide water. This cleaning caused a decrease in the thickness of the first layer 2a for a first silicon oxide film in the thick film portion region 9 from 5.3 nm to 3.5 nm.

The second thermal oxidation treatment was carried out by dry oxidation at a heating temperature of 900° C. The second layer 2b for a first silicon oxide film having a thickness of 2.5 nm was formed on the silicon substrate 1 in the thin film portion region 10 and the first layer 2a for a first silicon oxide film in the thick film portion region 9 by the second thermal oxidation treatment. Thus, the first silicon oxide film 2 was formed which includes the first layer 2a for a first silicon oxide film and the second layer 2b for a first silicon oxide film. The first thick film portion 13 including the first layer 2a for a first silicon oxide film and the second layer 2b for a first silicon oxide film in the thick film portion region 9 had a thickness of 6.0 (=3.5+2.5) nm, and the first thin film portion 14 formed by the second layer 2b for a first silicon oxide film in the thin film portion region 10 had a thickness of 2.5 nm.

The surface of the first thick film portion 13 and the surface of the first thin film portion 14 were nitrided by the plasma nitridation method. With this nitridation, the first silicon nitride region 11 containing nitrogen of 8.03×10²² atoms/cm³ was formed on the surface of the first thin film portion 14 and the first thick film portion 13.

The plasma nitridation method was carried out under the following conditions:

plasma nitridation apparatus: SPA (Slot Plane Antenna) apparatus manufactured by Tokyo Electron Ltd. (DPN may also be available). In this example, plasma nitridation was carried out by using SPA.

process gas name and flow rate: nitrogen (N₂)/argon (Ar)=1000/1000 sccm

power: 1500 W

pressure: 50 mTorr

wafer temperature: 400° C.

nitridation time: 120 seconds

thickness of nitride film: 1 nm

The heat treatment was carried out on the first silicon nitride region 11 at the heating temperature of 1000° C. to 1100° C. The condition for the heat treatment was the dry oxidation condition at 1 ton to 100 ton. The nitrogen atoms of the first silicon nitride region 11 were diffused at the depth 3 nm from the surface of the silicon substrate 1 directly below the first thin film portion 14 at a concentration of 8.03×10¹⁹ atoms/cm³ by the heat treatment.

The nitrogen concentration of the silicon substrate 1 was measured by using the X-ray Photoelectron Spectroscopy (XPS), and it was confirmed that the nitrogen concentration at the depth of 3 nm from the surface of the silicon substrate 1 was 1×10¹⁶/cm² to 2×10¹⁷/cm². The third thermal oxidation treatment was carried out by ISSG oxidation at the heating temperature of 1000° C. to 1100° C. Thus, the second silicon oxide film 4 was formed on the silicon substrate 1. In this way, the thickness of the second thick film portion 13a formed by the second silicon oxide film 4 in the thick film portion region 9 was 6.0 nm, and the thickness of the second thin film portion 14a formed by the second silicon oxide film 4 in the thin film portion region 10 was 3.0 nm.

The polysilicon film 5, the tungsten silicide film 6, the tungsten film 7, and the second silicon nitride film 8 were sequentially laminated on the second thick film portion 13a and the second thin film portion 14a. A lithography process and a dry etching process were carried out to form the first gate electrode 15a and the second gate electrode 15b. The silicon nitride 16 was formed on the second silicon nitride film 8. The silicon nitride 16 was covered on the side surfaces of the polysilicon film 5, the tungsten silicide film 6, and the tungsten film 7 by etch-back. The first gate electrode 15a and the second gate electrode 15b were buried by the insulating film (not shown). Thereafter, the surface was planarized by CMP (Chemical Mechanical Polishing), and the gate insulating film 20 was formed. The process progressed to the bit line forming step, such that the semiconductor device 30 of the first embodiment was completed.

### Example 2

Hereinafter, an example of the second embodiment will be described. First, as shown in FIG. 3A, the first thermal oxidation treatment was carried out to form the first silicon oxide film 2 having a thickness of 2.5 nm on the silicon substrate 1. In this case, with regard to the thermal oxidation treatment, radical oxidation (ISSG: In-Situ Steam

Generation) was carried out at the heating temperature of 1050° C. The surface of the first silicon oxide film 2 was nitrided by the plasma nitridation method. With this nitridation, the first silicon nitride region 11 containing nitrogen of 8.03×10²² atoms/cm³ was formed on the first silicon oxide film 2.

The photoresist 3 was patterned on the first silicon nitride region 11 in the thin film portion region 10. The first silicon nitride region 11 in the thick film portion region 9 was removed by wet etching using hot phosphoric acid with the photoresist 3 as a mask. The first silicon oxide film 2 in the thick film portion region 9 was removed by wet etching using hydrofluoric acid. Thereafter, the photoresist 3 was separated from the first silicon nitride region 11 in the thin film portion region 10.

The second thermal oxidation treatment was carried out. With regard to the heat treatment, an ISSG oxidation process was carried out at the heating temperature of 900° C. The second thick film portion 13a having a thickness of 6.0 nm was formed on the silicon substrate 1 in the thick film portion region 9 by the second thermal oxidation treatment. In the thin film portion region 10, oxidation did not progress since the first silicon nitride region 11 is present at the surface, and the thickness of the third thin film portion 14b did not change, that is, was 2.5 nm. Similarly to the first embodiment, the first gate electrode 15a and the second gate electrode 15b were formed. The subsequent process is the same as in the manufacturing method of the first embodiment, thus description thereof will be omitted.

### Example 3

Hereinafter, an example of the third embodiment will be described. First, as shown in FIG. 4A, the first thermal oxidation treatment was carried out to form the first silicon oxide film 2 having a thickness of 5.3 nm on the silicon substrate 1. In this case, with regard to the thermal oxidation treatment, radical oxidation (ISSG: In-Situ Steam Generation) was carried out at the heating temperature of 1050° C. The photoresist 3 was patterned on the first silicon oxide film 2 in the thick film portion region 9. Nitrogen was implanted into the first silicon oxide film 2 by ion implantation with the photoresist 3 as a mask.

Ion implantation was carried out under the following conditions:

apparatus: high-current implanter

dose: 1×10¹⁶ atoms/cm²

implantation energy: 5 to 50 KeV

At this time, implantation energy was adjusted such that the nitrogen concentration is 8.03×10¹⁹ atoms/cm³ at the silicon substrate 1 (at the depth 3 nm from the surface) having passed through the first silicon oxide film 2.

The photoresist 3 was separated from the first silicon oxide film 2. The first silicon oxide film 2 was removed by wet etching using hydrofluoric acid. The second thermal oxidation treatment was carried out on the silicon substrate 1. With regard to the second thermal oxidation treatment, radical oxidation (ISSG: In-Situ Steam Generation) was carried out at the heating temperature of 900° C. The fourth thick film portion 13c having a thickness of 6.0 nm and the fourth thin film portion 14c having a thickness of 2.5 nm were formed by the second thermal oxidation treatment.

The polysilicon film 5, the tungsten silicide film 6, the tungsten film 7, and the second silicon nitride film 8 were sequentially laminated on the fourth thick film portion 13c and the fourth thin film portion 14c to form the first gate electrode 15a and the second gate electrode 15b. The subsequent process is the same as in the first example, thus description thereof will be omitted.

The invention relates to a method of manufacturing a semiconductor device, and in particular, to a method of manufacturing a semiconductor device including gate electrodes having different heights on the same semiconductor substrate. The invention is available in the industry where a semiconductor device is manufactured and used.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of forming a semiconductor device, the method comprising:
selectively forming a nitrogen-diffusion region in a semiconductor substrate having first and second regions, the nitrogen-diffusion region being at a shallow level of the first region; and
carrying out a first heat treatment to form a first oxide layer over the semiconductor substrate, the first oxide layer including first and second portions, the first portion being in the first region, the second portion being in the second region, the first portion being thinner than the second portion.

2. The method according to claim 1, wherein selectively forming the nitrogen-diffusion region comprises:
forming a second oxide layer over the semiconductor substrate, the second oxide layer having third and fourth portions, the third portion being in the first region, the fourth portion being in the second region, the third portion being thinner than the fourth portion;
forming a nitrogen-introduced region in the third and fourth portions, the nitrogen-introduced region being at a shallow level of the second oxide layer;
carrying out a second heat treatment to cause a thermal diffusion of nitrogen from the nitrogen-introduced region through the third portion into the first region to form the nitrogen-diffusion region in the first region; and
removing the second oxide layer before carrying out the first heat treatment.

3. The method according to claim 2, wherein the second heat treatment is carried out in an oxygen atmosphere.

4. The method according to claim 2, wherein the second heat treatment is carried out at a temperature in the range of 1000° C. to 11000° C.

5. The method according to claim 2, wherein the nitrogen-introduced region is formed by a plasma nitridation method in the third and fourth portions.

6. The method according to claim 1, wherein selectively forming the nitrogen-diffusion region comprises:
forming a second oxide layer over the semiconductor substrate, the second oxide layer having third and fourth portions, the third portion being in the first region, the fourth portion being in the second region, the third portion being thinner than the fourth portion;
introducing nitrogen through the second oxide layer into the first region of the semiconductor device to form the nitrogen-diffusion region in the first region; and
removing the second oxide layer before carrying out the first heat treatment.

7. The method according to claim 1, wherein introducing nitrogen through the second oxide layer into the first region comprises an ion-implantation of nitrogen through the second oxide layer into the first region.

8. The method according to claim 1, wherein carrying out the first heat treatment comprises carrying out an in-situ stream generation oxidation process at a temperature in the range of 1000° C. to 11000° C.

9. The method according to claim 1, wherein carrying out the first heat treatment comprises carrying out a wet oxidation process at a temperature in the range of 800° C. to 900° C.

10. The method according to claim 1, wherein the nitrogen-diffusion region has a nitrogen concentration at a depth of 3 nm in the range of 1×10¹⁶ atoms/cm³ to 2×10¹⁷ atoms/cm³.

11. The method according to claim 1, further comprising:
forming a layered structure over the first and second portions; and
patterning the layered structure to form first and second gate insulating films and first and second gate electrodes, the first gate insulating film and the first gate electrode being in the first region, and the second gate insulating film and the second gate electrode being in the second region, the first gate insulating film being thinner than the second gate insulating film.

12. A method of forming a semiconductor device, the method comprising:
forming a first oxide film over first and second regions of a semiconductor substrate;
forming a nitrogen-diffusion region in the first oxide film;
selectively removing the nitrogen-diffusion region and the first oxide film to expose the second region of the semiconductor substrate, the nitrogen-diffusion region and the first oxide film remaining in the first region; and
carrying out a heat treatment to form a second oxide film over the second region of the semiconductor substrate, the second oxide film being thicker than the first oxide film.

13. The method according to claim 12, wherein the nitrogen-diffusion region is formed by a plasma nitridation method in the third and fourth portions.

14. The method according to claim 12, further comprising:
forming a layered structure over the first and second portions;
patterning the layered structure to form first and second gate insulating films and first and second gate electrodes, the first gate insulating film and the first gate electrode being in the first region, and the second gate insulating film and the second gate electrode being in the second region, the first gate insulating film being thinner than the second gate insulating film.

15. A method of forming a semiconductor device, the method comprising:
preparing a substrate having first and second shallow regions, the first shallow region being higher in nitrogen concentration than the second shallow region; and
thermally oxidizing the substrate.

16. The method according to claim 15, wherein thermally oxidizing the substrate comprises:
carrying out a first heat treatment to form a first oxide layer over the first and second shallow regions, the first oxide layer including first and second portions, the first portion being over the first shallow region, the second portion being over the second shallow region, the first portion being thinner than the second portion.

17. The method according to claim 16, wherein preparing the substrate comprises:
forming a second oxide layer having first and second portions over a semiconductor substrate having first and second regions, the first portion being in the first region, the second portion being in the second region, the first portion being thinner than the second portion;
introducing nitrogen into a shallow region of the first oxide layer; and
thermally diffusing nitrogen through the first portion into the first shallow region; and
removing the first oxide layer.

18. The method according to claim 16, wherein preparing the substrate comprises:
forming a second oxide layer over a semiconductor substrate, the second oxide layer having third and fourth portions, the third portion being in the first region, the fourth portion being in the second region, the third portion being thinner than the fourth portion;
introducing nitrogen through the second oxide layer into the first region to form the nitrogen-diffusion region in the first region; and
removing the second oxide layer before carrying out the first heat treatment.

19. The method according to claim 16, wherein preparing the substrate comprises:
forming a first oxide film over first and second regions of a semiconductor substrate;
forming a nitrogen-diffusion region in the first oxide film; and
selectively removing the nitrogen-diffusion region and the first oxide film to expose the second region of the semiconductor substrate, the nitrogen-diffusion region and the first oxide film remaining in the first region.

20. The method according to claim 16, further comprising:
forming a layered structure over the first and second portions;
patterning the layered structure to form first and second gate insulating films and first and second gate electrodes, the first gate insulating film and the first gate electrode being in the first region, and the second gate insulating film and the second gate electrode being in the second region, the first gate insulating film being thinner than the second gate insulating film.
